(19) United States
(12) Patent Application Publication
(10) Pub. No.: US 2010/0072061 A1
(43) Pub. Date: Mar. 25, 2010

(54) SPUTTERING APPARATUS FOR FORMING THIN FILM

(75) Inventor: Shinichi Morohashi, Yamaguchi (JP)

Correspondence Address: OSHA LIANG L.L.P., TWO HOUSTON CENTER, 909 FANNIN, SUITE 3500, HOUSTON, TX, 77010, US

(73) Assignee: YAMAGUCHI UNIVERSITY, Yamaguchi (JP)

(21) Appl. No.: 12/442,693

(22) PCT Filed: May 9, 2008
(86) PCT No.: PCT/JP2008/058621

§ 371 Date: Mar. 23, 2009

(30) Foreign Application Priority Data
Jun. 1, 2007 (JP) 2007-146575
Jul. 11, 2007 (JP) 2007-182014

(51) Int. Cl. C23C 14/35

(52) U.S. Cl. 204/298.12

(57) ABSTRACT

A sputtering apparatus for forming a thin film includes a pair of facing polygonal prism target holders in which a target is placed on each surface which is parallel to a rotation axis of a rotatable polygonal prism body. A magnetic pole group which includes either a plurality of magnets or a magnet and a yoke is disposed on a back surface of the target, and the magnetic pole group includes magnets or yokes of different magnetic pole directions.

### TECHNICAL FIELD

The present invention relates to a sputtering apparatus for forming a thin film. Such a sputtering apparatus is indispensably important in a thin film single-layer or multi-layer structured electronics, the electronic industry, the watch industry, the mechanical industry, and the optical industry.

### BACKGROUND ART

A sputtering apparatus for forming a thin film in a vacuum is very important in manufacturing electronic material that has a thin film single-layer or multi-layer structure and electronic devices to which such an electronic material is applied.

As a method for forming a thin film, there are a deposition technique, a sputtering technique and a chemical vapor deposition (CVD) technique.

Of these, the sputtering technique is widely used in various fields due to the advantage that a thin film can be formed safely from various materials, regardless of the type of substrate material, through a relatively simple apparatus without using toxic gas.

A principle of a sputtering technique will be briefly described below.

A thin film is formed by generating plasma inside a vacuum apparatus and causing ions in the plasma to hit a target, so that constituent atoms and molecules of a target surface are sputtered away and deposited on a substrate.

As illustrated in FIGS. 1 to 5, there are various sputtering apparatuses based on methods for generating ionization gas or discharge plasma, collision ion sources, types of applied voltage, and electrode structures.

The ion beam sputtering apparatus of FIG. 1 includes a gas introduction hole 8, an ion source 10, ion extracting, accelerating, and converging electrodes 12, ion beam 14, substrate 16, target 18, sputtering atoms 20, and exhaust 22. The ion beam sputtering apparatus illustrated in FIG. 1 forms a thin film in such a way that irradiation ions generated in an ion chamber are emitted into a sputtering chamber to sputter the target 18 such that sputtering atoms 20 are deposited on a substrate 16.

Depending on the method for generating the ions, an ion source 10 such as a hot cathode type Kaufman ion source or an electron cyclotron resonance (ECR) type ion source may be used.

In both cases, sputtering is performed by extracting an ion beam 14 such as an argon (Ar) ion beam to irradiate the target 18.

Sputtering is possible even when discharge pressure is low, e.g., equal to or less than 10−4 Torr and also a dense thin film with excellent surface smoothness can be formed since the amount of gas absorbed in the thin film is small, and the kinetic energy of the sputtering particle is large.

However, there is a problem in that the speed of depositing the thin film is low.

A diode sputtering apparatus of FIG. 2 includes a gas introduction hole 8, discharge plasma area 24, cathode drop area 26, anode 28, substrate 16, cathode (target) 18, insulator 32, water cooling 34, high voltage power source 36, vacuum pump 38, and vacuum chamber 40. In the double-pole sputtering apparatus illustrated in FIG. 2, ions in plasma are accelerated within the cathode drop area 26 to hit the target 18 to sputter, so that sputtered particles are flown onto the facing substrate 16 to form a thin film.

The diode sputtering apparatus may be classified as either a direct current (DC) sputtering apparatus or an alternating current (RF) sputtering apparatus, depending on the type of applying voltage.

A diode sputtering apparatus has a simple structure but also has the following disadvantages: 1) since plasma efficiency is low, the pressure of gas introduced to cause plasma has to be increased, so that a lot of gas is absorbed into a thin film; 2) since plasma efficiency is low, the speed for depositing the thin film is low; 3) γ electrons (secondary electrons) of high energy generated when ion gas hits the target directly hit a substrate which is facing the target, so that the substrate temperature is increased up to several hundred degrees during the deposition; and 4) since the target and the substrate are facing each other, some (recoil ions) of the ions that hit a target directly hit the substrate, and thus the substrate gets damaged and the proper composition is not formed in a multi-component thin film.

In order to solve the above problems of the diode sputtering apparatus, a magnetron sputtering apparatus has been introduced.

FIG. 3 illustrates a principle of a representative magnetron sputtering apparatus.

FIG. 3 shows an electric field 42, ions 44, arch of magnetic flux 46, target 18, and magnets 48. A magnetron sputtering apparatus may be classified as a DC sputtering apparatus or an RF sputtering apparatus according to the type of applying voltage.

As described above in the diode sputtering apparatus, γ electrons of high energy generated when the ions 44 hit the target 18 directly hit the substrate and thus cause the substrate temperature to increase. However they play an important role in ionizing gas with high energy to maintain the plasma discharge.

For this reason, a magnetron is disposed on the back surface of the target 18, as illustrated in the drawing, to form magnetic field parallel to the target surface and confine γ electrons emitted from the target surface within an area surrounding the target surface.

As a result, γ electrons more frequently collide with atmospheric gas, leading to advantages: 1) atmospheric gas is rapidly ionized to increase plasma efficiency (high-speed sputtering); and 2) a closed path is formed as illustrated in the drawing to prevent γ electrons of high energy from hitting the substrate, thereby suppressing increase in substrate temperature (low-temperature sputtering).

The drawbacks of a double-pole sputtering apparatus are considerably improved by disposing a magnetron, but because the substrate and the target are still facing each other, there are the following drawbacks: 1) it is difficult to completely suppress γ electrons and recoil ions from flowing to the substrate; and 2) it is difficult to sputter the ferromagnetic substance at low temperature and high speed when the target includes a ferromagnetic substance because magnetic flux of the magnetron is difficult to pass through the ferromagnetic substance portion sufficiently to form a magnetic field on a target surface large enough to define γ electrons.

Nevertheless, since the thin film can be formed at a high deposition speed with a relatively simple structure, the planar magnetron sputtering apparatus is widely used.

A facing target sputtering apparatus illustrated in FIG. 4 has been introduced to improve the drawbacks of the magnetron sputtering apparatus. The facing target sputtering apparatus in FIG. 4 includes targets 18, permanent magnets 50, anodes 28, substrate 16, γ electrons 52, negative ions 54, tuning circuit 56, and high-frequency power source 57.

The two targets 18 are disposed to face each other, and magnetrons (permanent magnets 50) having opposite magnetic poles are disposed on back surfaces of the targets 18, respectively.

γ electrons 52 emitted from a target surface as ionization gas which is atmospheric gas are confined in a space between the facing targets while generating high-density plasma.

Since the substrate 16 is disposed outside the plasma area, that is, at the side of the space between the facing targets 18, it is possible to completely suppress the γ electrons 52 and recoil ions incident on the substrate 16, and low-temperature and high-speed sputtering is possible.

Since high-density plasma can be generated by confining γ electrons, even though the pressure of atmospheric gas is reduced, a discharge is possible (on the order of 10−4 Torr).

In addition, the amount of atmospheric gas absorbed in the thin film is small, and low-temperature and high-speed sputtering of a ferromagnetic substance is possible.

A facing target sputtering apparatus is classified as either a DC sputtering apparatus or an RF sputtering apparatus according to a type of an applied voltage.

As can be seen in FIGS. 3 and 4, in the case of the planar magnetron sputtering apparatus, magnetic flux generated by a magnet disposed on the back surface of the target remains closed. On the other hand, in the case of the facing target sputtering apparatus, since the polarities of the magnets disposed on the back surfaces between the facing targets are opposite to each other, magnetic flux lines generated between the facing targets remains closed.

However, as is apparent from the drawings, the surface of the magnet opposite to the target cannot form closed magnetic flux lines, so leakage of magnetic flux line occurs.

Magnetic flux leakage from a back surface means that magnetic flux does not go between the facing target surfaces and the magnetic flux generated from the magnet is not efficiently induced to the facing target surfaces, and thus it is not an efficient magnet use.

In order to reduce the influence resulting from the problem, a thick yoke needs to be installed on a back surface of a magnetic pole opposite to the target to reduce leakage magnetic flux.

However, in this case, there is a problem in that the size of the structure is increased.

Magnetic flux of about 150 to 250 Oersted (Oe) is required between facing targets.

In order to generate large magnetic flux, a neodymium magnet can be used.

However, since magnetic flux is not efficiently induced due to the occurrence of magnetic flux leakage at a magnetic pole at the opposite side of the target as described above, the magnet has to be thicker.

In addition, since saturation magnetization of a yoke is limited, if the ferrous yoke is too thin, it is magnetically saturated, and the magnetic flux leaks from the back surface of the yoke.

Therefore, a yoke for reducing leakage magnetic flux needs to be designed with a larger thickness.

In the magnetron sputtering apparatus illustrated in FIG. 3, since magnetic flux remains closed in both the surface and the back surface of the magnet, it is satisfactory if the thickness sum of the magnet and the ferrous yoke is about 30 to 50 mm. However, in a conventional facing target sputtering apparatus, there is the problem that the thickness sum of the magnet and the ferrous yoke is about 100 mm.

Recently, most electronic devices or optical thin films employ a multi-layer thin film structure, and a multi-layer thin film needs to be formed while kept in a vacuum.

In order to manufacture a multi-layer thin film structure through the facing target sputtering apparatus illustrated in FIG. 4, facing target cathodes must be disposed in parallel as illustrated in FIG. 5, and thus the vacuum apparatus which accommodates the facing target sputtering apparatus is increased in size. FIG. 5 shows ferrous yokes 58, magnets 48, magnetic flux lines 60, and targets 18.

If the vacuum apparatus is increased in size, a vacuum pump having a faster exhaust velocity must be installed in order to reach the same vacuum degree, and thus there is a cost disadvantage.

FIG. 6 illustrates a rotating box-type facing target sputtering apparatus, including magnets 48, targets 18, and magnetic flux lines 60.

The rotating box-type facing target sputtering apparatus not only has the advantages of a conventional facing target sputtering apparatus that as γ electrons generated during the sputtering move back and forth between targets, a collision probability between the γ electrons and the residual gas is increased, so that discharge can be performed at a low residual gas pressure due to high-density plasma (in the order of 10⁻¹ Pa), and the amount of residual gas absorbed into a thin film is small) but also resolves the structural problem of increase in apparatus size in order to prevent magnetic flux leakage. Thus, a small structure and a small vacuum device according thereto can be realized, whereby a multi-layer thin film structure can be manufactured with high throughput and low cost.

The features are as follows:

A pair of polygonal prism target holders, in which a target 18 is disposed on each of surfaces parallel to a rotatable polygonal prism rotation axis, are disposed to face each other.

Magnets 48 are disposed so that magnetic flux lines 60 generated by the magnets 48 disposed on back surfaces of the targets 18 of each polygonal prism target holder can be completely closed inside a polygonal prism target holder and the polarities of the magnets 48 Scan be alternately changed.

In the pair of polygonal prism target holders, since the polarities of the magnets 48 disposed on the back surfaces of the facing targets 18 are opposite to each other, the magnetic flux lines 60 are closed between the facing targets 18.

In order to deposit different types of thin films, deposition is performed by rotating the facing polygonal prism target holders in opposite directions, respectively, to make different target surfaces face each other.

The polarity of each of the magnets 48 disposed on the back surfaces of the facing targets 18 becomes opposite to that prior to rotated, and the direction of the magnetic flux lines 60 becomes opposite to that before the rotation.

By successively rotating a pair of polygonal prism target holders, as many multi-layer thin films as the number of targets attached to a polygonal prism target holder can be manufactured “in situ.”

As related arts, there are Patent Documents 1 and 2.

They were filed by the applicant of the present invention.

In Patent Documents 1 and 2, polygonal prism target holders are disposed to face each other, magnets are disposed on the back surface of the target, but a magnetic pole direction of the magnets disposed on the back surface of each target is only one direction.

They do not disclose that a yoke is used as part of a magnetic pole on the back surface of the target.
Patent Document 1: Japanese Patent Application Laid-Open No. 2003-183827
Patent Document 2: Japanese Patent Application Laid-Open No. 2004-52005

FIG. 7 shows targets 18, magnets 48, magnetic flux lines 60, and target holders 64 of a rotating box-type facing target sputtering apparatus. As illustrated in FIG. 7, in the rotating box-type facing target sputtering apparatus, the magnets 48 are disposed so that the magnetic flux constitutes a closed magnetic circuit inside a box, but a closed circuit is not configured outside the polygonal prism target holder.

Therefore, as can be seen in the drawing, plasma generated between the facing the targets 18 can be scattered.

Higher plasma density is required in order to form a high quality thin film.

In order to prevent this, a method for installing an anti-adhesive & magnetic shield plate 66 as illustrated in FIG. 8 can be considered, but it is difficult to completely prevent magnetic flux from leaking outside the polygonal prism target holder. FIG. 8 shows targets 18, target holders 64, magnets 48, magnetic flux lines 60, and leakage magnetic flux lines 62.

As the substrate diameter increases, the targets 18 need to be larger in size than the substrate, and the magnets 48 disposed on the back surface of the targets 18 also need to be larger in diameter.

However, it is difficult and expensive to increase the magnet diameter.

As illustrated in FIG. 9, a method for disposing many small-diameter magnets 48 can be considered, but in this case, a problem occurs in the uniformity of magnetic flux lines 60.

The target is reduced by sputtering, but the targets 18 are non-uniformly reduced due to the non-uniformity of magnetic flux lines 60, and thus the targets 18 cannot be efficiently used, leading to the non-uniformity in thickness of the thin film.

Also, the magnetic flux line problem occurring outside a polygonal prism target holder is not yet resolved.

In a facing target sputtering apparatus, the pattern of magnetic flux lines between facing targets can be changed by changing the pattern of the magnetic pole of the back surface of a target.

Since there is a case where efficient sputtering can be realized by changing the pattern of the magnetic pole depending on usage or material, merit for changing the pattern of magnetic flux lines between the facing targets is large, but in a facing target sputtering apparatus it is difficult to change the pattern of a magnetic flux line between facing targets.

Also, even if the pattern of magnetic flux lines was changed, since only polarity could be changed, it could only select limited magnetic flux lines.

### SUMMARY OF THE INVENTION

Embodiments of the present invention are directed to reducing the leakage of magnetic flux occurring outside a target holder, enabling easy change of the pattern of magnetic flux lines between the facing targets, and providing a rotating box type multi-facing target sputtering apparatus which allows selection of various types of magnetic flux lines.

In some aspects, the invention relates to a sputtering apparatus for forming a thin film, comprising:

a pair of facing polygonal prism target holders in which a target is placed on each surface which is parallel to a rotation axis of a rotatable polygonal prism body,
wherein a magnetic pole group which includes either a plurality of magnets or a magnet and a yoke is disposed on a back surface of the target, and the magnetic pole group includes magnets or yokes of different magnetic pole directions.

Preferably, the present invention can have the following aspects:

Each magnet or yoke of the magnetic pole group is disposed so that adjacent magnets or yokes have alternately different magnetic pole directions.
Magnetic pole groups, respectively, disposed on the back surfaces of targets of the facing polygonal prism target holder have polarities opposite to each other.
Magnetic pole groups, respectively, disposed on the back surfaces of targets of the facing polygonal prism target holder have the same polarity.
In the magnetic pole group, magnets or yokes of different magnetic pole directions are concentrically disposed.
In the magnetic pole group, magnets or yokes of different magnetic pole directions are disposed in a check pattern.
Magnetic pole groups, respectively, disposed on back surface of targets of the facing polygonal prism target holder have different magnetic pole patterns from each other, and a characteristic of magnetic field between facing target is changed by rotating the polygonal prism target holder.
Targets of the polygonal prism target holder are made of different materials from each other.
Targets of the polygonal prism target holder are made of the same material, and long-time sputtering is performed by rotating the polygonal prism target holder.
A removable protection plate which prevents a surface of the target from being contaminated when forming the thin film is disposed between adjacent targets of the polygonal prism target holders.
A magnetic shield plate is disposed between adjacent targets of the polygonal prism target holder.
A mechanism which disposes the pair of polygonal prism target holders to face each other is configured as one module, and one or more modules are disposed in a vacuum chamber.
One or more vacuum chambers in which one or more modules are installed are connected.
The yoke has one end which comes in contact with or is close to the back surface of the target and another end which comes in contact with a magnetic pole of a side of the magnet opposite to the target.
At least some of the yokes are movable, and as those yokes move, the yokes are separated from the back surface of the target and at least one side of the magnet.
A magnetic pole piece which increases uniformity of the magnetic flux density made by the magnet is disposed between the back surface of the target and the magnet.
A target back surface side end of the yoke is close to the magnetic pole piece, and the yoke and the magnetic pole piece are separated from each other by moving the at least some of the yokes.
A pattern of magnetic flux lines between facing targets is changed by moving some or all of the yokes of the magnetic pole group.
A back yoke is disposed on a side of the magnetic pole group opposite to the target.
Any magnet can be used as the yoke and the magnetic pole piece, but a ferrous magnet is commonly used.

By high-functionally disposing a magnetic pole group, the structural problem of a conventional rotating box-type facing target sputtering apparatus in that magnetic flux lines do not constitute a closed circuit outside a polygonal prism target holder is resolved, and a high-performance rotating box-type multi-facing target sputtering apparatus which can perform multi-facing, compact and low-temperature sputtering and efficiently cope with an increment of a substrate diameter by realizing high plasma density between facing targets can be obtained.

The apparatus can be used to manufacture high-quality, high-performance electronic devices of various fields which demand low-temperature sputtering that does not cause damage. For example, the apparatus may be used to manufacture the following: organic EL devices; liquid crystal displays in which indium tin oxide (ITO) as a transparent electrode has to be deposited without causing damage since it is weak to heat; superconductive tunnel junctions in which a tunnel barrier with a thickness of 1 nm (1/one billion meter) is sandwiched between superconductive thin films and needs interface control of an atom order; ferromagnetic junctions in which a tunnel barrier is sandwiched between ferromagnetic thin films; soft X-ray projection lithography which is used as a semiconductor lithography technique after a 70 nm designed rule (64 Gbit DRAM); X-ray multi-layer mirrors which are employed in X-ray microscopes for physical property evaluation; and light emitting diodes.

The rotating box-type multi-facing target sputtering apparatus with the above-described configuration according to embodiments of the present invention can significantly reduce a leakage magnetic flux line which passes through portions other than between facing targets.

This is because as magnetic pole groups which include magnets or yokes having different magnetic pole directions face each other, a magnetic closed circuit can be formed between facing magnetic pole groups, and leakage magnetic flux which passes through the outside of the polygonal prism target holder can be significantly reduced.

Since there are no unnecessary leakage magnetic flux lines, magnetic flux can be concentrated between facing targets, leading to high sputtering effect.

Also, as a magnetic pole group of each side of the polygonal prism target holder can have a different magnetic pole pattern, the pattern of the magnetic flux lines between facing targets can be changed by rotating the polygonal prism target holder, whereby a magnetic flux line pattern suitable for a use or a target material can be selected.

Further, as some or all of yokes between facing targets can be operated, a magnetic closed circuit, which is different from a magnetic closed circuit formed, before operated, by a series of magnetic pole groups which include a magnet and a yoke, can be formed, a pattern of the magnetic flux lines between facing targets can be changed, and a magnetic flux line pattern suitable for a desired use or target material can be selected.

The magnetic piece disposed between the back surface of the target and the magnet serves to increase magnetic flux uniformity of magnetic flux lines between facing targets.

Furthermore, as a back yoke is formed on the side of a magnetic pole group opposite to the target, magnetic flux density between targets can be increased.

The rotating box-type multi-facing target sputtering apparatus according to embodiments of the present invention can select a magnetic flux line pattern between facing targets among the following modes according to rotation of a target holder and movement of a yoke:

(1) Facing mode (mode in which magnetic flux lines are parallel to each other between facing targets)
(2) Magnetron mode (mode in which magnetic flux lines remain closed on each target surface)
(3) Hybrid mode (hybrid mode of a facing mode and a magnetron mode)
(4) Diode-like mode (mode in which magnetic flux lines do not exist between targets)

### BRIEF DESCRIPTION OF THE DRAWINGS

FIG. 1 is a view illustrating a principle of an ion beam sputtering apparatus;

FIG. 2 is a view illustrating a principle of a double-pole sputtering apparatus;

FIG. 3 is a view illustrating a principle of a planar magnetron sputtering apparatus;

FIG. 4 a view illustrating a principle of a typical facing target sputtering apparatus;

FIG. 5 a view illustrating a typical facing target sputtering apparatus for forming a four-layer thin film;

FIG. 6 is a view illustrating a typical rotating box-type facing target sputtering apparatus;

FIG. 7 is a view illustrating a magnetic circuit formed by magnetic flux lines inside and outside a typical rotating box-type facing target sputtering apparatus;

FIG. 8 is a view illustrating a typical rotating box-type facing target sputtering apparatus with an anti-adhesive & magnetic shield plate mounted therein;

FIG. 9 is a view illustrating a typical rotating box-type facing target sputtering apparatus with an anti-adhesive & magnetic shield plate mounted therein to cope with an increment of a substrate diameter (increment of a target diameter);

FIG. 10 is a view illustrating a hybrid mode sputtering method of a rotating box-type four-facing target sputtering apparatus according to an embodiment 1;

FIG. 11 is a view illustrating a case where an anti-adhesive & magnetic shield plate is mounted in a hybrid mode sputtering method of a rotating box-type four-facing target sputtering apparatus according to the embodiment 1;

FIG. 12 is a view illustrating a magnetron mode sputtering method of a rotating box-type four-facing target sputtering apparatus according to the embodiment 1;

FIG. 13 is a view illustrating a case where an anti-adhesive & magnetic shield plate is mounted in a magnetron mode sputtering method of a rotating box-type four-facing target sputtering apparatus according to the embodiment 1;

FIG. 14 is a view illustrating a case where an anti-adhesive & magnetic shield plate is mounted in a hybrid mode sputtering method of a rotating box-type six-facing target sputtering apparatus according to the embodiment 1;

FIG. 15 is a view illustrating a case where an anti-adhesive & magnetic shield plate is mounted in a hybrid mode sputtering method of a rotating box-type six-facing target sputtering apparatus according to the embodiment 1 to cope with an increment of a substrate diameter (increment of a target diameter);

FIG. 16 is a view illustrating an embodiment of a magnet group arrangement in the case of a small size target for coping with a small size substrate and illustrates an arrangement of a target, a holder and a magnet group when seen from one side of a polygonal prism target holder and when seen inside a holder;

FIG. 17 is a view illustrating an embodiment of a magnet group arrangement in the case of a medium size target for coping with a medium size substrate and illustrates an arrangement of a target, a holder and a magnet group when seen from one side of a polygonal prism target holder and when seen inside a holder;

FIG. 18 is a view illustrating an embodiment of a magnet group arrangement in the case of a large size target for coping with a large size substrate and illustrates an arrangement of a target, a holder and a magnet group when seen from one side of a polygonal prism target holder and when seen inside a holder;

FIG. 19 is a view illustrating an embodiment of a magnet group arrangement in the case of a large size rectangular target for coping with a large size rectangular substrate and illustrates an arrangement of a target, a holder and a magnet group when seen from one side of a polygonal prism target holder and when seen inside a holder;

FIG. 20 is a view illustrating an embodiment of an arrangement in which rod-shaped magnet groups are uniformly disposed and adjacent magnets have polarities opposite to each other in the case of a large size target for coping with a large size substrate, and illustrates an arrangement of a target, a holder and a magnet group when seen from one side of a polygonal prism target holder and when seen inside a holder;

FIG. 21 is view illustrating a back yoke disposed on a side of a magnetic pole group opposite to a target in the rotating box-type four-facing target sputtering apparatus shown in FIGS. 10 and 12;

FIG. 22 is a view illustrating a hybrid mode sputtering method of a rotating box-type multi-facing target sputtering apparatus according to an embodiment 2;

FIG. 23 is a view illustrating a case where an anti-adhesive & magnetic shield plate is mounted in a hybrid mode sputtering method of a rotating box-type multi-facing target sputtering apparatus according to the embodiment 2;

FIG. 24 is a view illustrating a magnetron mode sputtering method of a rotating box-type multi-facing target sputtering apparatus according to the embodiment 2;

FIG. 25 is a view illustrating a facing mode sputtering method of a rotating box-type multi-facing target sputtering apparatus according to the embodiment 2;

FIG. 26 is a view illustrating a facing mode sputtering method of a rotating box-type multi-facing target sputtering apparatus according to the embodiment 2 (movement of back yoke);

FIG. 27 is a view illustrating a hybrid mode sputtering method of a rotating box-type multi-facing target sputtering apparatus according to the embodiment 2;

FIG. 28 is a view illustrating a facing mode sputtering method of a rotating box-type multi-facing target sputtering apparatus according to the embodiment 2;

FIG. 29 is a view illustrating a facing mode sputtering method of a rotating box-type multi-facing target sputtering apparatus according to the embodiment 2;

FIG. 30 is a view illustrating a diode-like mode sputtering method of a rotating box-type multi-facing target sputtering apparatus according to the embodiment 2;

FIG. 31 is a view illustrating a non-parallel arrangement (no back yoke) of a magnetic pole group according to an embodiment 3;

FIG. 32 is a view illustrating a non-parallel arrangement (back yoke) of a magnetic pole group according to the embodiment 3; and

FIG. 33 is a view illustrating a non-parallel arrangement (part of magnetic pole group is a back yoke) of a magnetic pole group according to the embodiment 3.

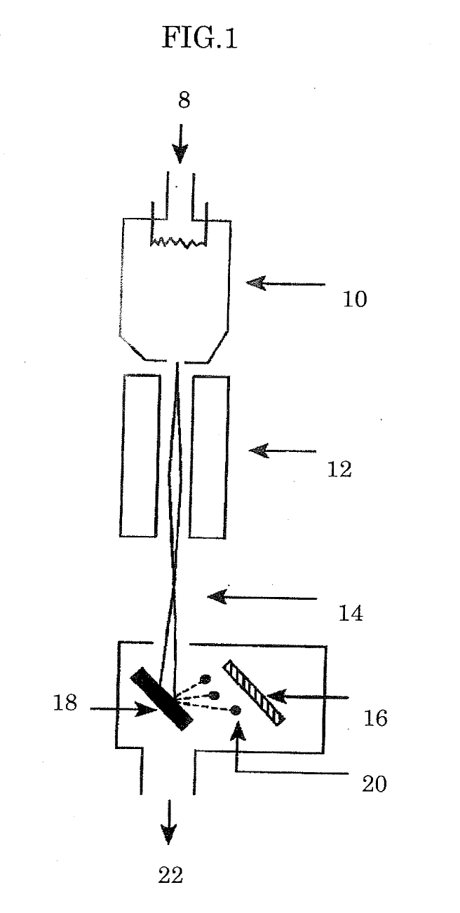

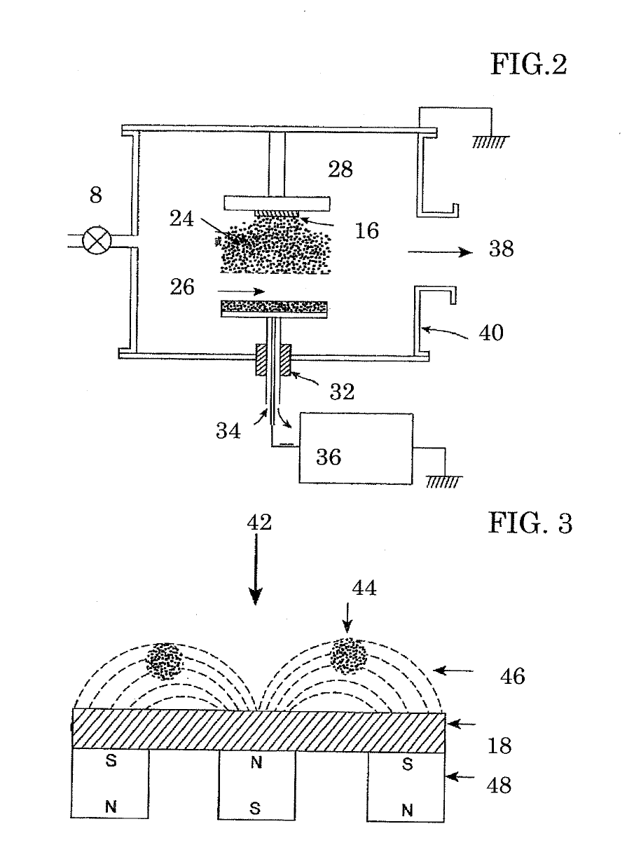

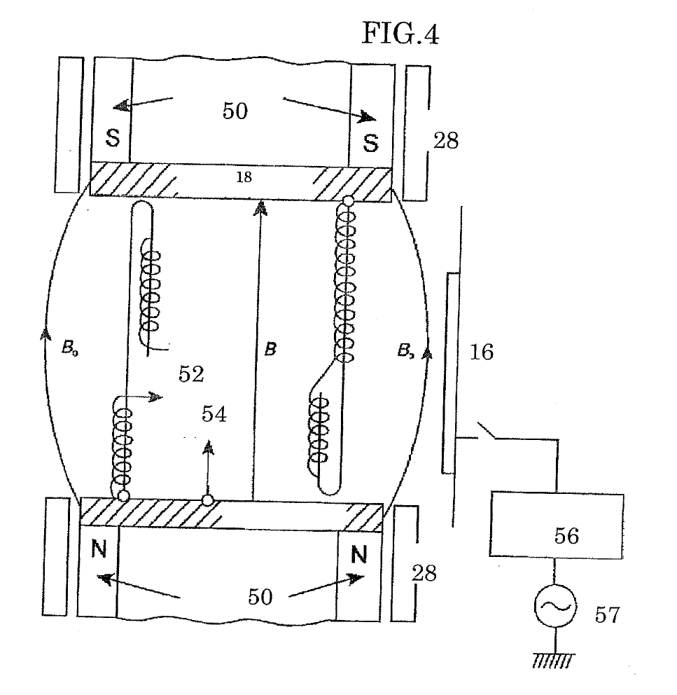

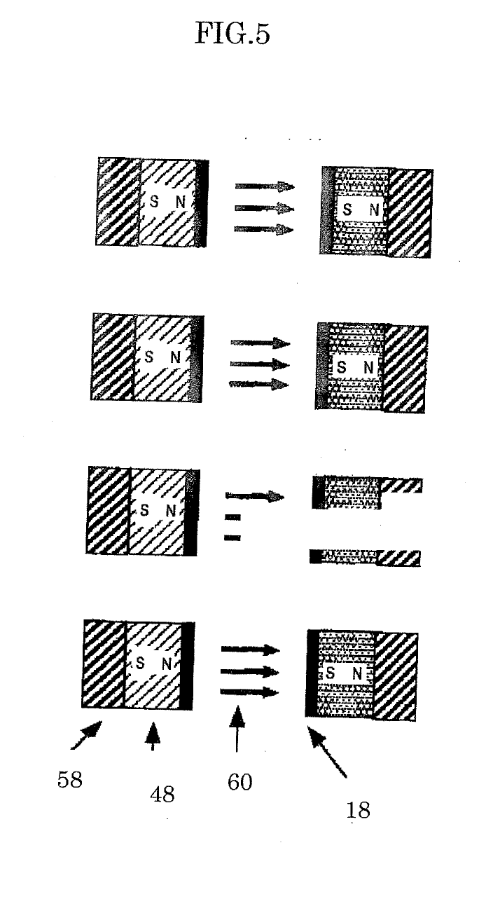

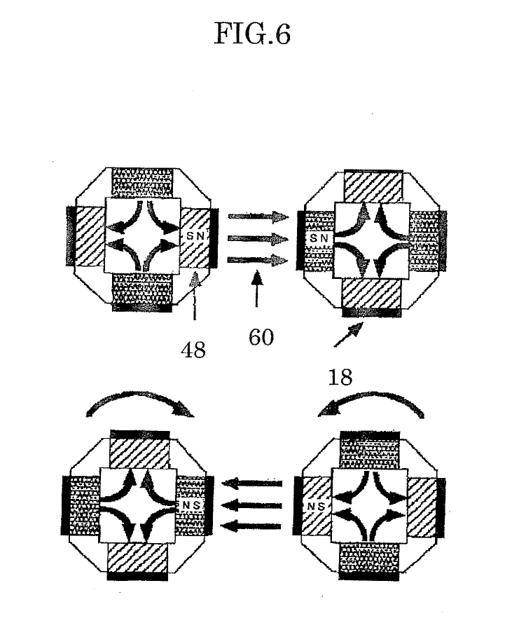

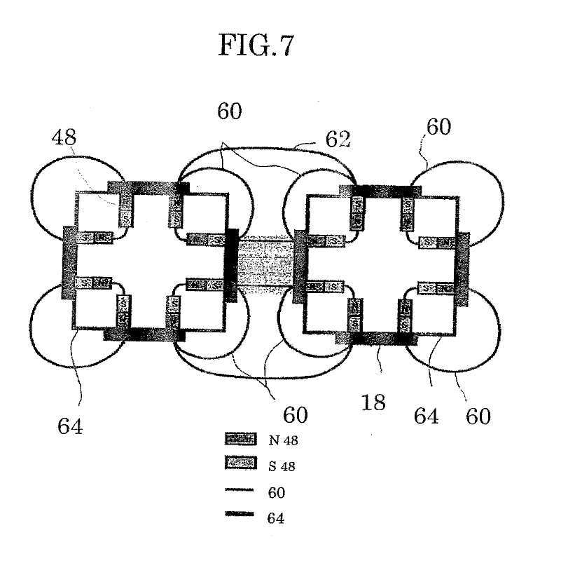

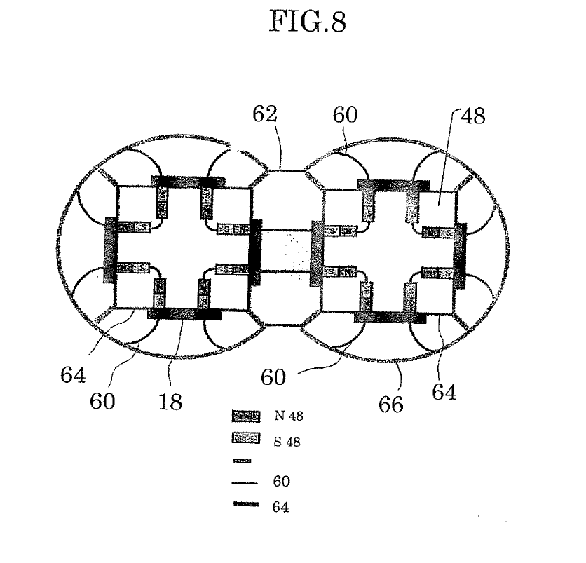

### DETAILED DESCRIPTION

### Embodiment 1

As one of the embodiments of the present invention, an example (embodiment 1) in which a plurality of magnets are used as a magnetic pole group will be described.

In embodiment 1, a magnet group is high-functionally disposed to thereby resolve the structural problem of a conventional rotating box-type facing target sputtering apparatus in that magnetic flux lines do not constitute a closed circuit outside a polygonal prism target holder and to implement a high-performance rotating box-type multi-facing target sputtering apparatus that can perform multi-facing, compact and low-temperature sputtering and efficiently cope with an increment of a substrate diameter by realizing high plasma density between facing targets.

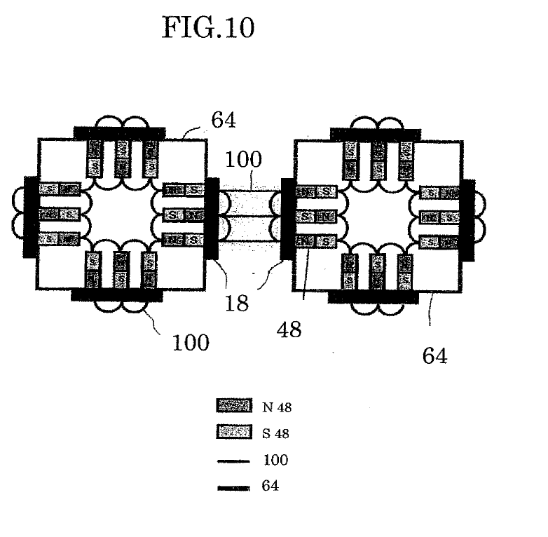

FIGS. 10 to 20 illustrate the present embodiment.

FIG. 10 illustrates the case of a four-facing target, rotating box-type multi-facing target sputtering apparatus as one embodiment of the present invention.

In each of two boxes, magnetic flux lines 100 are closed inside and outside the polygonal prism target holders 64.

At the same time, in the facing polygonal prism target holders 64, magnetic flux lines 100 are closed even between facing targets 18 since polarities of the magnet groups are opposite to each other.

As the sputtering method, a hybrid mode in which a facing mode and a magnetron mode coexist is used.

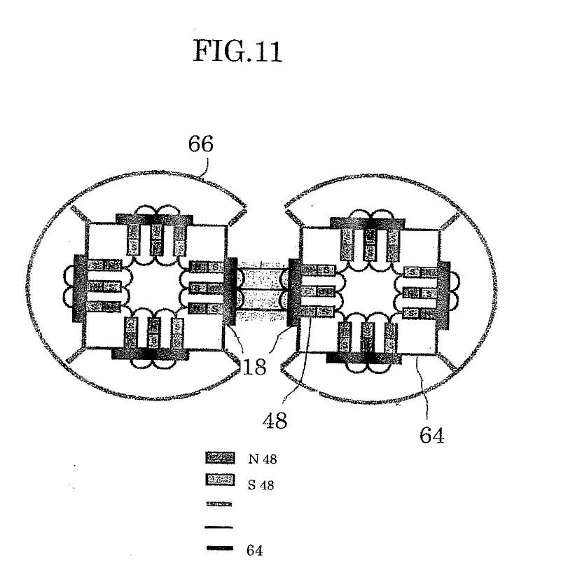

FIG. 11 illustrates a case where an anti-adhesive & magnetic shield plate 66 is mounted in the rotating box-type four-facing target sputtering apparatus illustrated in FIG. 10.

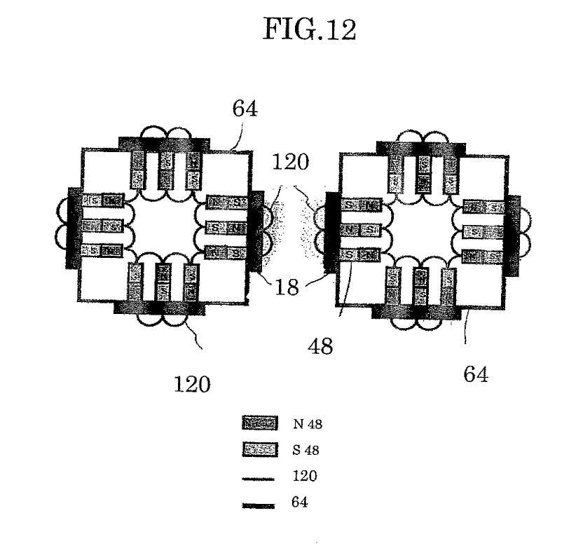

FIG. 12 illustrates a case of a four-facing target, rotating box-type multi-facing target sputtering apparatus as one embodiment of the present invention.

In each of two boxes, magnetic flux lines 120 are closed inside and outside the polygonal prism target holders 64.

In the facing polygonal prism target holders 64, magnetic flux lines 120 repel each other between facing targets 18 since polarities of magnet groups are the same as each other.

As the sputtering method, a magnetron mode is used.

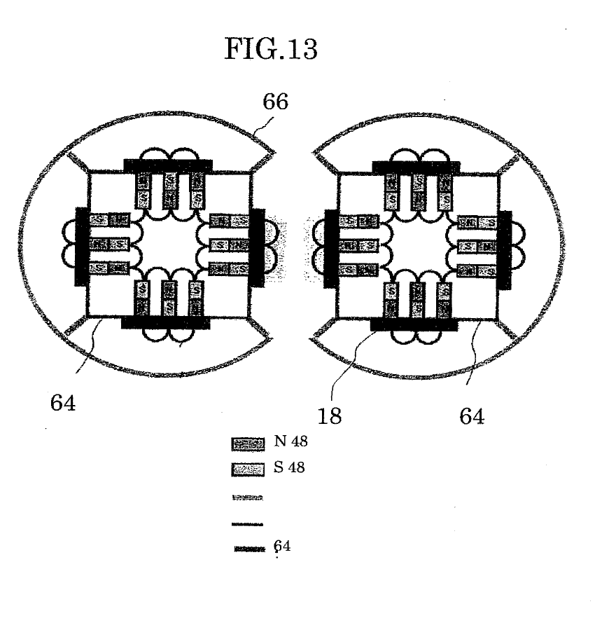

FIG. 13 illustrates a case where an anti-adhesive & magnetic shield plate 66 is mounted in the rotating box-type four-facing target sputtering apparatus illustrated in FIG. 12.

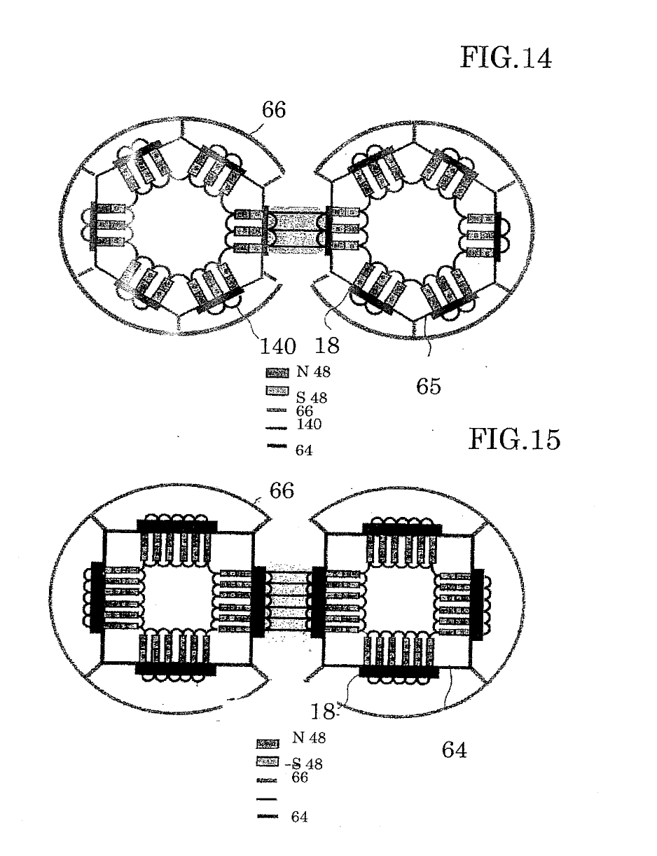

FIG. 14 illustrates a case of a hexagonal prism target holder, that is, a six-facing target, as one embodiment of the present invention, wherein a hybrid mode in which a facing mode and a magnetron mode coexist is used as the sputtering method, and an anti-adhesive & magnetic shield plate 66 is mounted.

As long as magnetic flux lines 140 are closed, an octagonal or dodecagonal prism or other polygonal prism target holders such as target holders 65 can be used.

Also, a magnetron-only mode can be arranged.

FIG. 15 illustrates a case of a four-facing target in which a target diameter is increased to cope with an increment of a substrate diameter as one embodiment of the present invention, wherein a hybrid mode in which a facing mode and a magnetron mode coexist is used as the sputtering method, and an anti-adhesive & magnetic shield plate 66 is mounted.

A magnetron-only mode can be arranged.

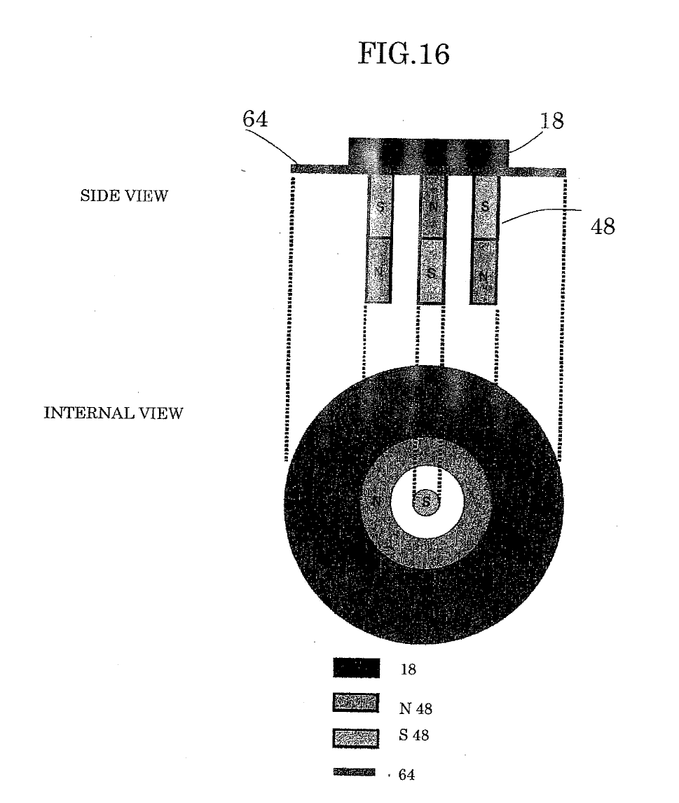

FIGS. 16 to 20 illustrate embodiments of a magnet group arrangement according to the present invention.

The drawings illustrate an arrangement of a target 18, a holder 64 and a magnet group of magnets 48 when seen from one side of a polygonal prism target holder (side view) and when seen inside a holder (internal view).

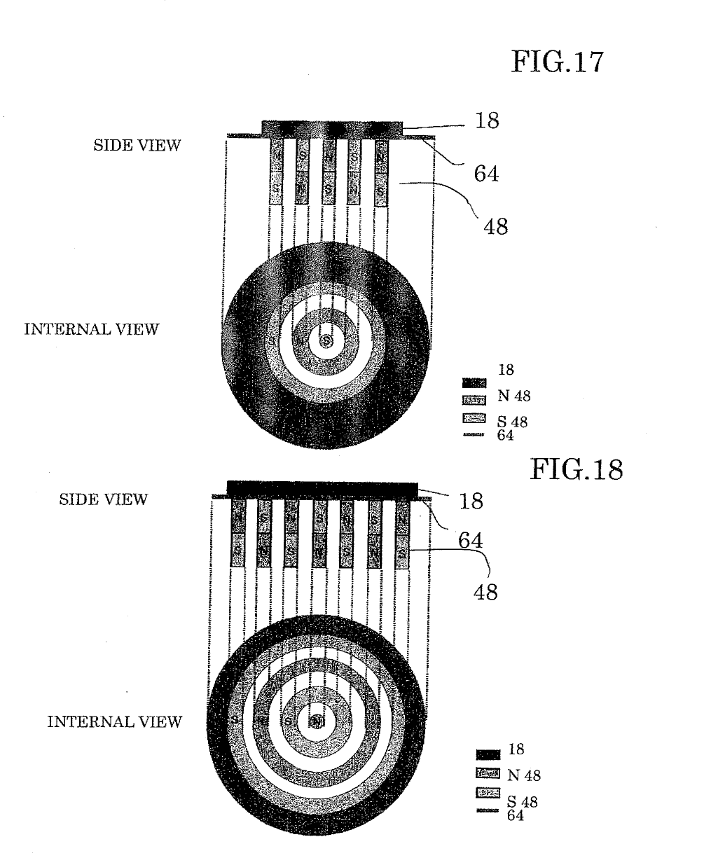

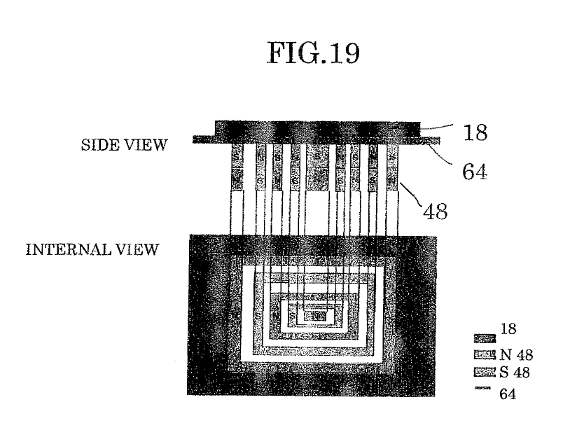

FIG. 16 illustrates an arrangement of a magnet group when the target 18 has a small size to cope with a small-size substrate; FIG. 17 illustrates an arrangement of a magnet group when the target 18 has a medium size to cope with a medium size substrate, FIG. 18 illustrates an arrangement of a magnet group when the target 18 has a large size to cope with a large size substrate; and FIG. 19 illustrates an arrangement of a magnet group when the target 18 has a rectangular shape and a large size to cope with a large size rectangular-shaped substrate.

A rod-shaped magnet is disposed at the center, and a concentric cylindrical magnet which has a magnetic pole opposite to the rod magnet is disposed.

The number of concentric cylindrical magnets is increased as the size is increased.

Of course, the magnets are disposed so that their polarities are opposite to each other.

Due to this arrangement, a magnetic circuit that remains closed both inside and outside the polygonal prism target holder can be formed.

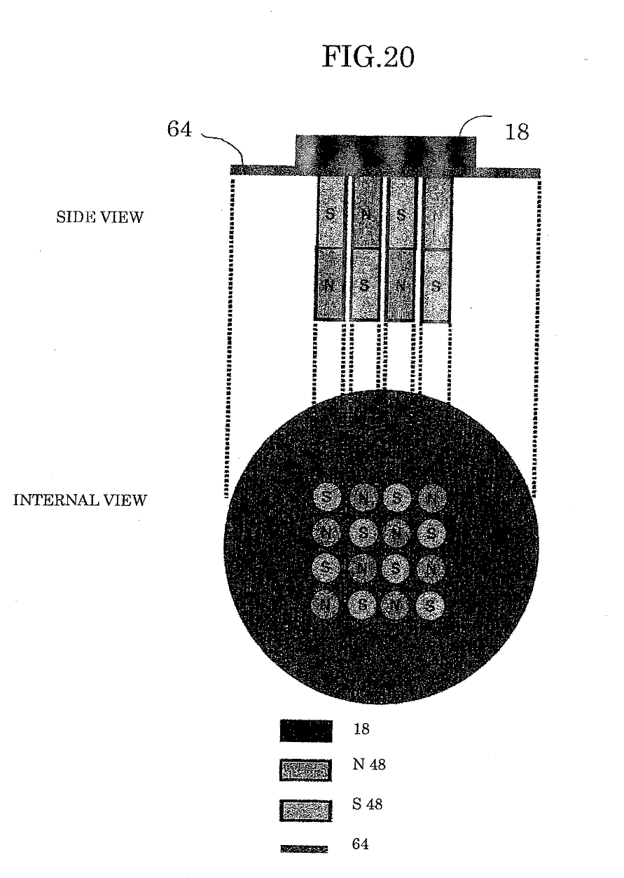

FIG. 20 illustrates an arrangement of a magnet group when the target 18 has a large size to cope with a large size substrate, wherein rod-shaped magnets are uniformly disposed, and adjacent magnets are disposed to have polarities opposite to each other.

In the embodiments, a back yoke can be additionally disposed on a side of a magnet group opposite to a target to thereby increase magnetic flux density between targets.

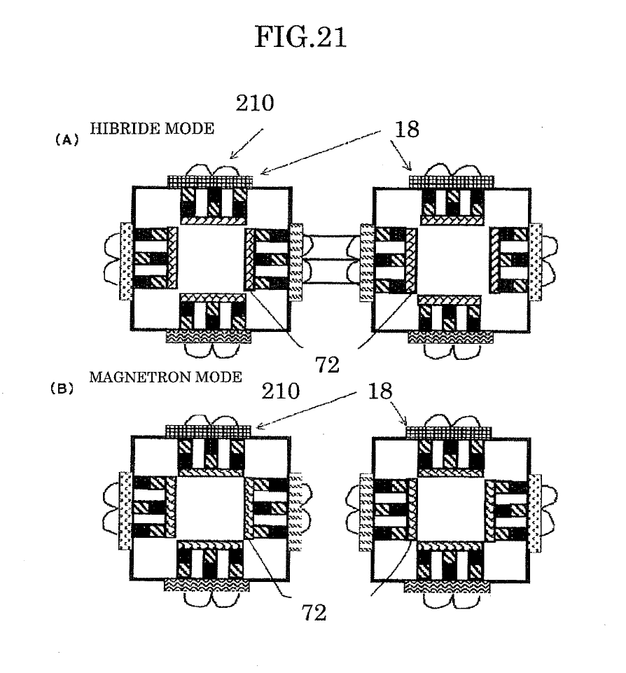

FIG. 21 illustrates a case where a back yoke 72 is installed.

In FIG. 21, (A) illustrates an example of a hybrid mode (facing mode+magnetron mode), and (B) illustrates an example of a magnetron mode.

Magnetic flux density between targets is increased by about 12% due to the back yoke 72.

As the facing polygonal prism target holders 64 are rotated in the same direction or in a reverse direction, target surfaces of different materials face each other, and the direction of magnetic flux lines 210 generated between the targets 18 at the moment becomes opposite to a direction before rotated.

Meanwhile, in the present embodiment, a rotation surface of target holders is parallel to the horizontal surface, but direction of the rotation surface is not limited if it satisfies the requirements of the claims.

Also, the distance between the pair of facing polygonal prism target holders can be adjusted by moving the polygonal prism target holders in parallel with both their rotation axes.

Also, as illustrated in FIG. 11, one or more modules in which the pair of facing polygonal prism target holder mechanisms are configured can be installed in a vacuum chamber.

In this case, as many multilayer thin films as the number of targets installed in each polygonal prism target holder×the number of modules can be manufactured, and an improvement of the throughput can be expected.

Also, a multi-layer thin film can be manufactured by a configuration in which one or more vacuum chambers having one or more modules are connected, and thus an improvement can be expected.

DC sputtering or RF sputtering can be performed depending on the type of applied power.

Even if a substrate is in a floating state during sputtering, bias sputtering is also possible by additionally applying a bias voltage.

Sputtering in which DC sputtering is added to AC sputtering is also possible.

One example of thin film sputtering according to the present embodiment is described.

A niobium (Nb) target was used, the distance between the target and the substrate was about 9 cm, and a deposition speed of about 125 nm/min was obtained at argon (Ar) pressure of 2×10−4 Torr, an applying current of DC 2.0 A, and a voltage of DC 350 V.

Nb is a superconductive material, and reaches a superconductive state at a temperature (Tc) of 9.3 K, but it is very sensitive such that its Tc falls down to 8.3 K when 1 atomic percent of oxygen is mixed.

In a Nb thin film manufactured under the above conditions, Tc was the same value, that is, 9.3 K.

A residual resistance ratio which is represented by a resistance ratio between room temperature and 10 K had a large value of about 4.

Accordingly, a high-quality thin film into which the amount of residual gas introduced is small was formed.

### Embodiment 2

As another embodiment of the present invention, an example (embodiment 2) in which magnets and yokes are used as a magnetic pole group will be described.

In the embodiment 2, a series of magnetic pole groups which include a magnet and a yoke are high-functionally disposed to thereby resolve the structural problem of a conventional rotating box-type multi-facing target sputtering apparatus in that magnetic flux lines do not constitute a closed circuit outside a polygonal prism target holder and to implement a high-performance rotating box-type multi-facing target sputtering apparatus that can perform multi-facing, compact and low-temperature sputtering by realizing high plasma density between facing targets and can select an appropriate magnetic flux line, which is suitable for a use or a target material, between facing targets by operating some or all of yokes of a magnet group between facing targets.

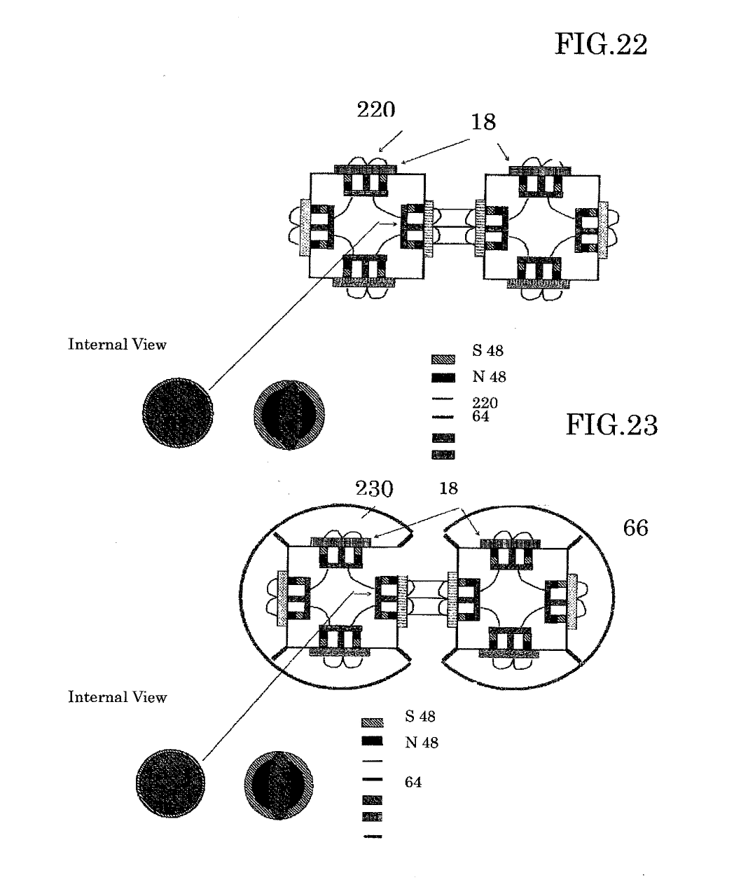

FIGS. 22 to 29 illustrate the present embodiment.

FIG. 22 illustrates a case of a four-facing target, rotating box-type multi-facing target sputtering apparatus as one embodiment of the present invention.

In each of two boxes, magnetic flux lines 220 of a series of magnetic pole groups which include magnets and yokes remain closed inside and outside the polygonal prism target holder.

At the same time, in the polygonal prism target holders 64 which are facing each other, magnetic flux lines 220 remain closed even between facing targets since polarities of a series of magnetic pole groups are opposite to each other.

As the sputtering method, a hybrid mode in which a facing mode and a magnetron mode coexist is used.

FIG. 23 illustrates a case where an anti-adhesive & magnetic shield plate 66 is mounted in the rotating box-type four-facing target sputtering apparatus illustrated in FIG. 22.

In the present embodiment, a four-facing target sputtering apparatus is described, but the present invention can be applied to a six-, eight- or more-facing target sputtering apparatus in which a magnetic closed circuit is configured by a hexagonal, octagonal or other polygonal prism target holder.

The left-side lower portions of FIGS. 22 and 23 illustrate examples of different yoke forms.

An opposite end portion of the yoke to the back surface of the target can have a random shape so long as it forms a magnetic circuit with a magnet. In the present embodiment, examples of circular and elliptical shapes are illustrated.

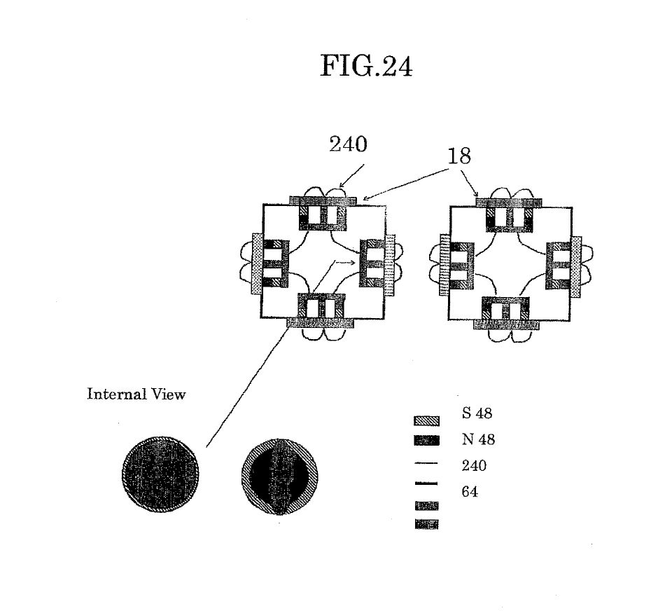

FIG. 24 illustrates a case of a four-facing target, rotating box-type multi-facing target sputtering apparatus as one embodiment of the present invention.

In each of two boxes, magnetic flux lines 240 of a series of magnetic pole group, which include magnets and yokes remain closed inside and outside a polygonal prism target holder.

In the facing polygonal prism target holders 64, magnetic flux lines 240 repel each other between facing targets since polarities of magnetic pole groups are the same as each other.

As the sputtering method, a magnetron mode is used.

As illustrated in FIG. 23, an anti-adhesive & magnetic shield plate 66 can be mounted in the rotating box-type four-facing target sputtering apparatus.

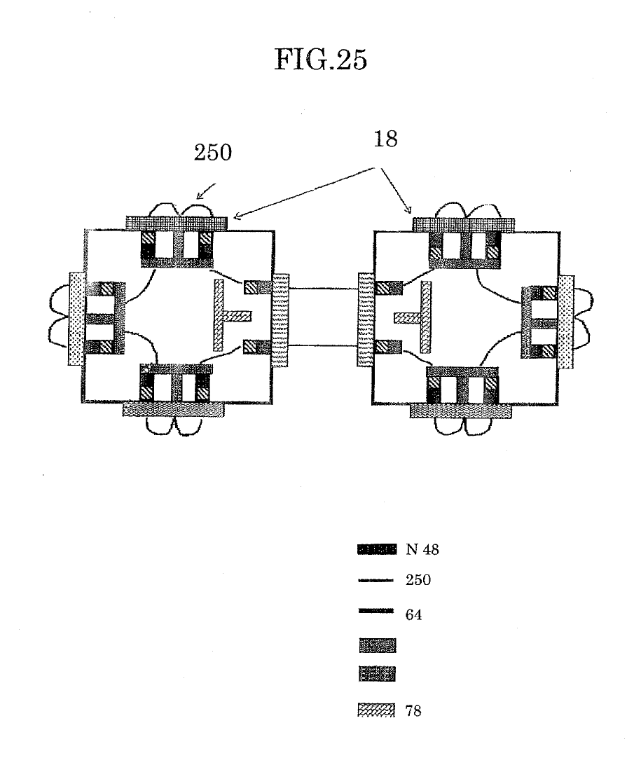

FIG. 25 illustrates a case of a four-facing target, rotating box-type multi-facing target sputtering apparatus as one embodiment of the present invention.

Operating yokes 72 move only between facing targets to constitute a magnetic closed circuit, which is different from a magnetic closed circuit formed before operation, by a series of magnetic pole groups which include magnets and yokes, so that the pattern of magnetic flux lines 250 between facing targets can be changed.

As the sputtering method, a facing mode is used.

It is different from that of FIG. 22 in the fact that the yoke between facing targets moves.

As in FIG. 23, an anti-adhesive & magnetic shield plate 66 can be mounted in the rotating box-type four-facing target sputtering apparatus.

That is, in FIG. 25, the pattern of magnetic flux lines 250 becomes “a hybrid mode (hybrid mode of a facing mode and a magnetron mode)” in a state which connects the yoke to the back surface of the target as in FIG. 22, and becomes “a facing mode (a mode in which magnetic flux lines are parallel to each other between facing targets)” as illustrated in FIG. 25 when the yokes 78 are separated from the back surface of targets 18.

Also, in FIG. 25, the polarity patterns of the facing magnetic pole groups disposed on the back surfaces of the respective targets can have the same polarity (repulsive polarities) by rotating at least one of target holders 64.

However, in this case, when the yokes 78 come in contact with the back surface of the targets 18, “a magnetron mode (a mode in which a magnetic flux line remains closed on each target surface)” is formed as illustrated in FIG. 11, and when the yokes 78 are apart from the back surface of the targets 18, since a magnetic flux line hardly comes out of a target surface, a “diode-like mode (a mode in which a magnetic flux line does not exist between targets)” is formed.

As described above, the magnetic flux line pattern can be variously selected between facing targets by a combination of movement of the yoke and rotation of a target holder.

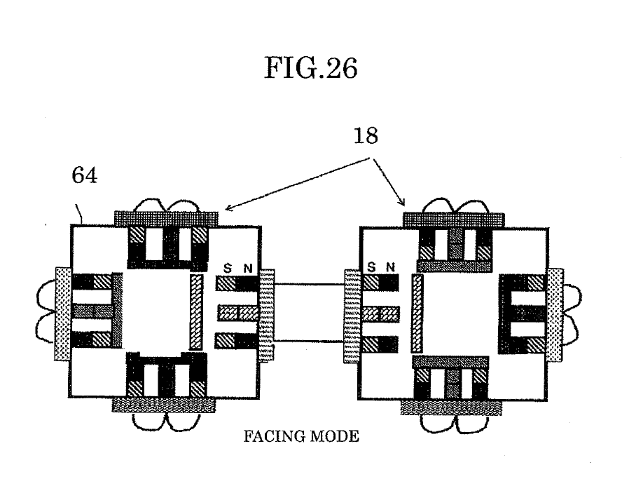

In FIG. 25, the magnetic pole yoke and a back yoke move together. However, even when moving only the back yoke without moving the magnetic pole yoke as illustrated in FIG. 26, magnetic flux generated from the magnetic pole yoke can be greatly reduced, and thus the same effect as that of FIG. 25 can be obtained.

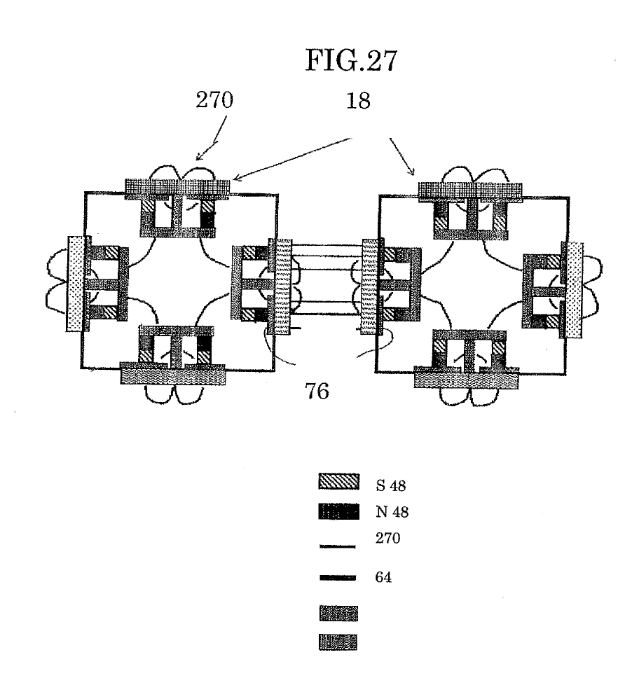

FIG. 27 illustrates a case of a four-facing target, rotating box-type multi-facing target sputtering apparatus as one embodiment of the present invention.

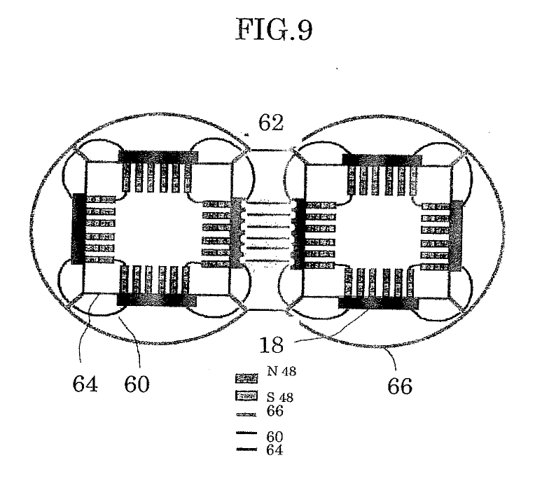

Unlike the embodiment illustrated in FIG. 9, magnetic pole pieces 76 are disposed directly below targets 18 to thereby increase uniformity of magnetic flux made by the magnets 48.

As the sputtering method, a hybrid mode is used.

It is possible to cope with an increment of the substrate diameter, that is, an increment of the target diameter.

The operating yokes 78 and the magnetic pole pieces 76 are not integrated with each other but instead are separated.

As in FIG. 23, an anti-adhesive & magnetic shield plate 66 can be mounted in the rotating box-type four-facing target sputtering apparatus.

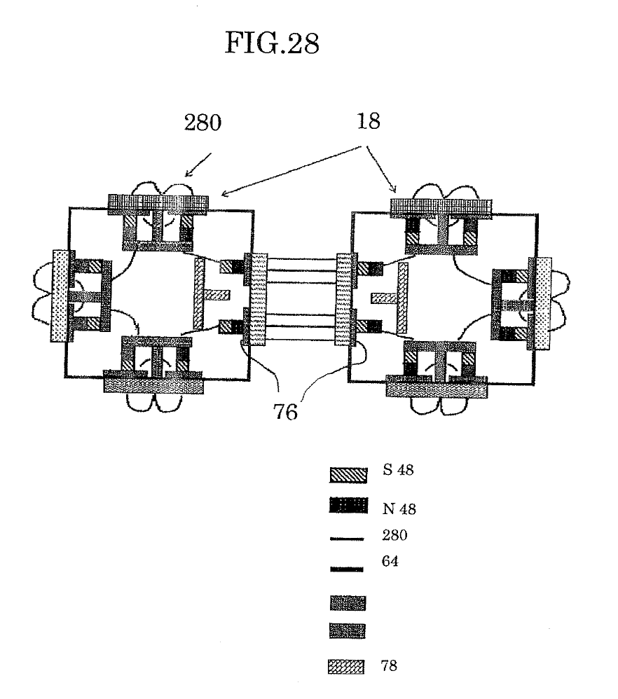

FIG. 28 illustrates a case of a four-facing target, rotating box-type multi-facing target sputtering apparatus as one embodiment of the present invention.

The operating yokes 78 move only between facing targets 18 to constitute a magnetic closed circuit, which is different from a magnetic closed circuit formed before operation, by a series of magnetic pole groups which include a magnet and a yoke, so that the pattern of the magnetic flux lines 280 between facing targets can be changed.

Unlike the embodiment illustrated in FIG. 25, a magnetic pole piece is disposed directly below the target to thereby increase uniformity of magnetic flux made by the magnets.

The operating yoke and the magnetic pole piece are not integrated with each other but instead are separated.

As the sputtering method, a facing mode is used.

It is possible to cope with an increment of a substrate diameter, that is, an increment of the target diameter.

As illustrated in FIG. 23, an anti-adhesive & magnetic shield plate 66 can be mounted in the rotating box-type four-facing target sputtering apparatus.

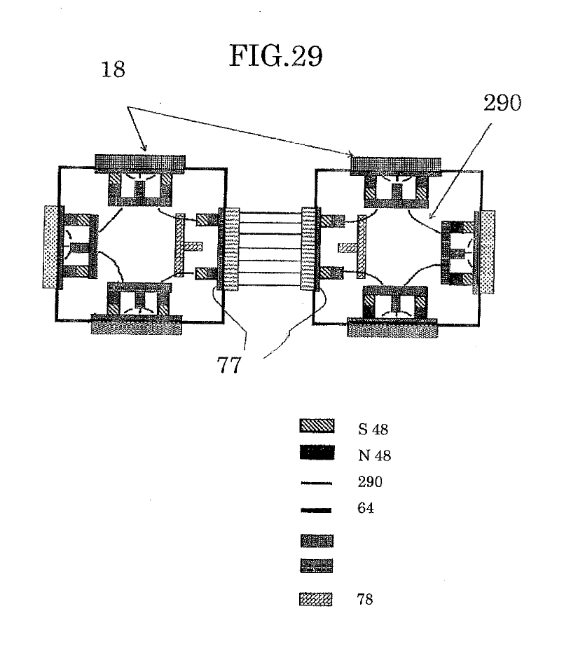

FIG. 29 illustrates a case of a four-facing target, rotating box-type multi-facing target sputtering apparatus as one embodiment of the present invention.

The operating yokes 78 move only between facing targets to constitute a magnetic closed circuit, which is different from a magnetic closed circuit formed before operation, by a series of magnetic pole groups which include a magnet and a yoke, so that the pattern of the magnetic flux lines 290 between facing targets can be changed.

Unlike the embodiments illustrated in FIGS. 27 and 28, magnetic pole pieces 77 are not dispersed directly below the targets 18, and a single magnetic pole piece 77 extends to cover the whole back surface of the target 18, thereby increasing uniformity of magnetic flux made by the magnets.

The operating yokes 78 and the magnetic pole pieces 77 are not integrated with each other but instead are separated.

The front end of the operating yokes 78 does not come in contact with the magnetic pole pieces 77.

An operating yoke forms a magnetic closed circuit with the magnetic pole piece when not operated, and the operating yoke itself has a non-magnetized arrangement when operated.

As the sputtering method, a facing mode is used.

It is possible to cope with an increment of a substrate diameter, that is, an increment of the target diameter.

As illustrated in FIG. 23, an anti-adhesive & magnetic shield plate 66 can be mounted in the rotating box-type four-facing target sputtering apparatus.

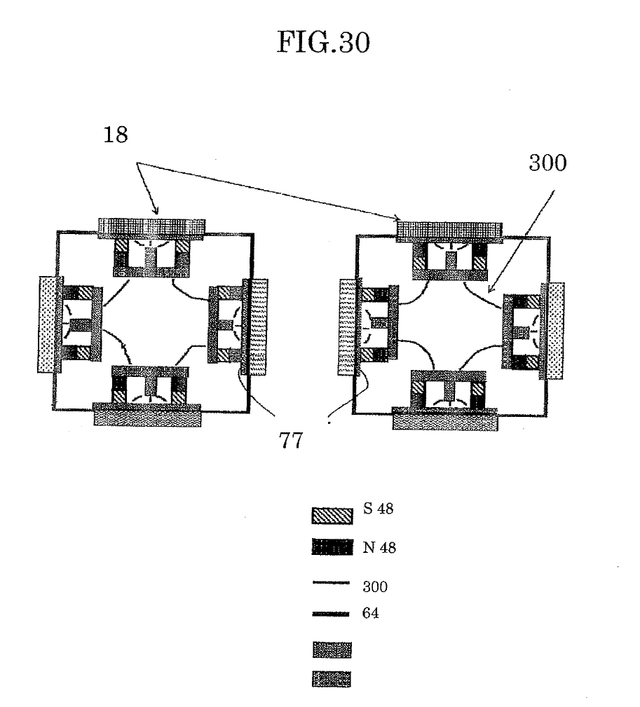

FIG. 30 illustrates a case of a four-facing target, rotating box-type multi-facing target sputtering apparatus as one embodiment of the present invention.

Unlike FIG. 29, the yoke has an arrangement that contacts a magnet, that is, a magnetized state.

As the sputtering method, a diode-like mode is used.

In each of two boxes, the magnetic flux lines 300 of a series of magnet groups that include a magnet and a yoke remain closed inside and outside a polygonal prism target holder.

The operating yokes move only between facing targets to constitute a magnetic closed circuit which is different from a magnetic closed circuit formed, before operation, by a series of magnetic pole groups which include magnets and yokes, so that the pattern of the magnetic flux lines between facing targets can be changed.

Unlike the embodiments illustrated in FIGS. 27 and 28, the magnetic pole pieces 77 are not dispersed directly below the targets 18, and a single magnetic pole piece 77 extends to cover the whole back surface of the target 18, thereby increasing the uniformity of magnetic flux made by the magnet.

The operating yokes and the magnetic pole pieces are not integrated with each other but instead are separated.

The front end of the operating yokes do not come in contact with the magnetic pole pieces.

However, the operating yokes form a magnetic closed circuit with the magnetic pole piece when not operated, and the operating yoke itself has a non-magnetized arrangement when operated.

It is possible to cope with an increment of a substrate diameter, that is, an increment of the target diameter.

As illustrated in FIG. 23, an anti-adhesive & magnetic shield plate 66 can be mounted in the rotating box-type four-facing target sputtering apparatus.

By rotating facing polygonal prism target holders 64 in the same direction or in a reverse direction, target surfaces of different materials face each other, and the direction of the magnetic flux lines generated between targets at the moment is opposite to a direction before rotation.

Meanwhile, in the present embodiment, a rotation surface of the target holder is parallel to a horizontal surface, but the direction of the rotation surface is not limited so long as it satisfies the requirement of the claims.

Also, a distance between the pair of facing polygonal prism target holders 64 can be adjusted by moving polygonal prism target holders 64 in parallel with their respective rotation axes.

Also, one or more modules including the pair of facing polygonal prism target holder mechanisms can be installed in a vacuum chamber.

In this case, as many multi-layer thin films as the number of targets installed in the polygonal prism target holder×the number of modules can be manufactured, and an improvement of the throughput can be expected.

Also, a multi-layer thin film can be manufactured by a configuration in which one or more vacuum chambers having one or more modules installed therein are connected, and thus an improvement can be expected.

DC sputtering or RF sputtering can be performed depending on the type of applied power.

Even though a substrate is in a floating state during sputtering, bias sputtering is also possible by additionally applying a bias voltage.

Also, sputtering in which DC sputtering is added to AC sputtering is also possible.

### Embodiment 3

When a magnetic circuit is formed using a plurality of magnetic pole groups having different polarities, the magnetic pole groups are commonly disposed in parallel with each other so that the strength of magnetic field become parallel due to different polarities.

However, the present invention is not so limited; the magnetic pole groups can be disposed in non-parallel relation with each other.

Due to a non-parallel arrangement, in a hybrid mode in which a facing mode and a magnetron mode coexist, magnetic flux density can be increased by an amount corresponding to the facing mode.

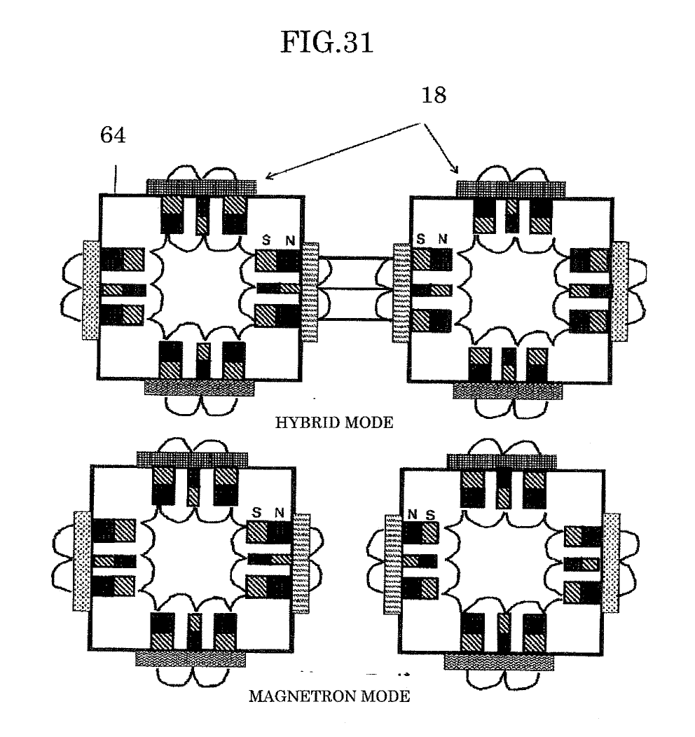

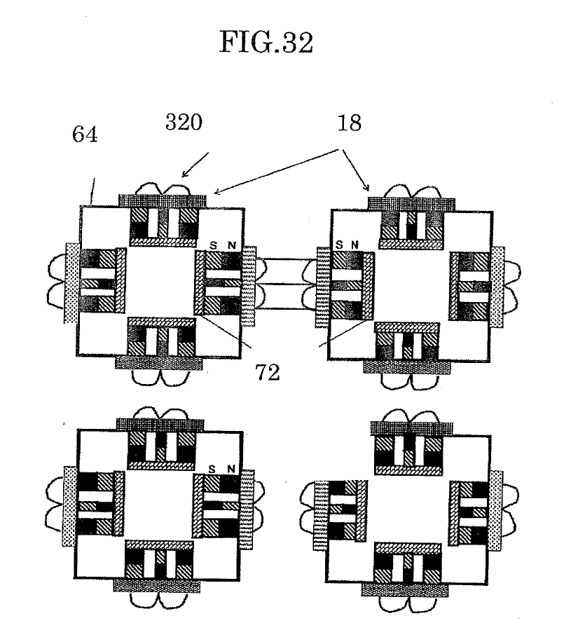

FIGS. 31 and 32 illustrate an example of a non-equilibrium arrangement of magnet groups.

In FIG. 31, there is no back yoke, and in FIG. 32, back yokes 72 are arranged.

In each of the drawings, the view in the upper portion illustrates a magnet group arrangement for forming a hybrid mode, and the view in the lower portion illustrates a magnet group arrangement for forming a magnetron mode.

In these examples, the outer magnets are stronger than the inner magnet.

By making the strength of outer magnets stronger, when it is in a hybrid mode, magnetic flux density can be increased by an amount corresponding to a facing mode.

The same effect can be obtained even when a yoke is used as part of a magnetic pole group.

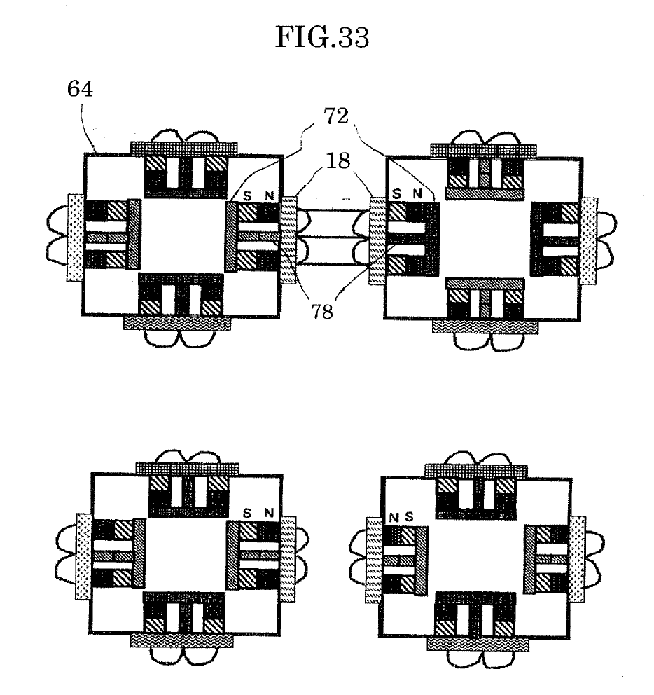

FIG. 33 illustrates a non-parallel arrangement when a yoke is used as part of a magnetic pole group.

The exemplary embodiments of the present invention have been described hereinbefore, but it will be apparent that the present invention is not limited to the above-described embodiments, and various modifications can be made to the above-described embodiments within the technical spirit of the present invention and within the scope of the appended claims.

In the embodiments described above, targets are facing each other, but the present invention is not so limited.

For example, facing targets can be inclined a little in a direction for facing substrates, respectively, so that deposition speed of the substrate can be faster.

Also, rotation axes of the target holders do not need to be parallel to each other and can be inclined according to the installation location of a substrate.

1. A sputtering apparatus for forming a thin film, comprising:
a pair of facing polygonal prism target holders in which a target is placed on each surface which is parallel to a rotation axis of a rotatable polygonal prism body,
wherein a magnetic pole group which includes either a plurality of magnets or a magnet and a yoke is disposed on a back surface of the target, and the magnetic pole group includes magnets or yokes of different magnetic pole directions.

2. The sputtering apparatus of claim 1, wherein each magnet or yoke of the magnetic pole group is disposed so that adjacent magnet or yokes become alternately different magnetic pole directions.

3. The sputtering apparatus of claim 1, wherein magnetic pole groups, respectively, disposed on back surface of targets of the facing polygonal prism target holder have polarities opposite to each other.

4. The sputtering apparatus of claim 1, wherein magnetic pole groups, respectively, disposed on back surface of targets of the facing polygonal prism target holder have the same polarity.

5. The sputtering apparatus of claim 1, wherein in the magnetic pole group, magnets or yokes of different magnetic pole directions are concentrically disposed.

6. The sputtering apparatus of claim 1, wherein in the magnetic pole group, magnets or yokes of different magnetic pole directions are disposed in a check pattern.

7. The sputtering apparatus of claim 1, wherein magnetic pole groups, respectively, disposed on back surface of targets of the facing polygonal prism target holder have different magnetic pole patterns from each other, and a characteristic of magnetic field between facing target is changed by rotating the polygonal prism target holder.

8. The sputtering apparatus of claim 1, wherein targets of the polygonal prism target holder are made of different materials from each other.

9. The sputtering apparatus of claim 1, wherein targets of the polygonal prism target holder are made of the same material, and long-time sputtering is performed by rotating the polygonal prism target holder.

10. The sputtering apparatus of claim 1, wherein a removable protection plate which prevents a surface of the target from being contaminated when forming a thin film is disposed between adjacent targets of the polygonal prism target holders.

11. The sputtering apparatus of claim 1, wherein a magnetic shield plate is disposed between adjacent targets of the polygonal prism target holder.

12. The sputtering apparatus of claim 1, wherein a mechanism which disposes the pair of polygonal prism target holders to face each other is configured as one module, and one or more modules are disposed in a vacuum chamber.

13. The sputtering apparatus of claim 12, wherein one or more vacuum chambers in which one or more modules are installed are connected.

14. The sputtering apparatus of claim 1, wherein the yoke has one end which comes in contact with or is close to a back surface of the target and the other end which comes in contact with a magnetic pole of a side of the magnet opposite to the target.

15. The sputtering apparatus of claim 1, wherein at least some of the yokes are movable, and as the least some of the yokes move, the yoke is separated from a back surface of the target and at least one side of the magnet.

16. The sputtering apparatus of claim 1, wherein a magnetic pole piece which increases uniformity of magnetic flux density made by the magnet is disposed between a back surface of the target and the magnet.

17. The sputtering apparatus of claim 1, wherein a target back surface side end of the yoke is close to the magnetic pole piece, and the yoke and the magnetic poly piece are separated from each other by moving the at least some of the yokes.

18. The sputtering apparatus of claim 1, wherein a pattern of a magnetic flux line between facing targets is changed by moving some or all of the yokes of the magnetic pole group.

19. The sputtering apparatus of claim 1, wherein a back yoke is disposed on a side of the magnetic pole group opposite to the target.

20. The sputtering apparatus of claim 2, wherein magnetic pole groups, respectively, disposed on back surface of targets of the facing polygonal prism target holder have polarities opposite to each other.

21. The sputtering apparatus of claim 2, wherein magnetic pole groups, respectively, disposed on back surface of targets of the facing polygonal prism target holder have the same polarity.
